(19) United States
(12) Patent Application Publication
(10) Pub. No.: US 2005/0139248 A1
(43) Pub. Date: Jun. 30, 2005

(54) Thermoelectricity generator

(76) Inventor: Richard J. Strnad, Plano, TX (US)

Correspondence Address: Richard J. Strnad, 2524 Preston Rd., #204, Plano, TX, 75093, US

(21) Appl. No.: 10/750,106

(22) Filed: Dec. 30, 2003

(51) Int. Cl. H01L 35/28; H01L 35/30

(52) U.S. Cl. 136/205; 136/208; 136/209

(57) ABSTRACT

A non-linear, high efficiency thermoelectricity generator assembly contains disk shaped thermoelectric cells electrically connected in series to each other. The assembly may be used as a generator of electricity or as a cooling apparatus. In the electricity generating mode an external heat source is required. In the cooling mode, a power source is required to provide the necessary electrical energy.

### BACKGROUND OF THE INVENTION

1. Field of the Invention

The present invention relates to a thermoelectricity generator and more particularly to an improved thermoelectricity generator that performs the conversion between thermal energy and electrical energy, and a method of fabricating the thermoelectric component of the generator. Further, the present invention relates to a thermoelectricity generator assembly which is fabricated by employing such thermoelectric components.

2. Description of the Related Art

A thermoelectric generator converts heat into electrical energy. The conversion in a single junction involves generating low voltages and high currents.

Thermoelectric voltage generation from the thermal gradient, present across the conductor, is inseparably connected to the generation of thermal gradient from applied electric current to the conductor. This interconversion of heat and electrical energy for power generation or heat pumping is based on the Seebeck and Peltier effects. Thermoelectricity is prolific in two representative applications. The first application is the thermocouple junction and the second application is the electricity generator. The thermocouples are one of the most widely used temperature sensors in test and development work. They usually consist of two wires of different materials connected together. The voltages generated due to the temperature excursions are in the microvolt range and are converted into temperature. The technique of generating appliance electricity from thermoelectric junctions is more involved. The conversion efficiency is low however some desirable features of these devices outweigh this handicap because of other desirable functions they offer. The thermoelectric power generators are very reliable, quiet, vibration free and nonpolluting to the environment. They provide power to many military and space projects and to floating and terrestrial weather stations, cardiac pacemakers, and navigational buoys, not attainable otherwise.

Thermoelectricity was discovered to exist between two different metals, however in later years, semiconducting materials were found to have superior qualities. The material thermoelectric quality is expressed in terms of the resistivity ρ, thermal conductivity κ and Seebeck coefficient α, as follows:

$$Z = \frac{{α}^{2}}{ρκ}$$

This relationship is useful for comparing the relative thermoelectric efficiencies of various materials, in which the current densities at both contact electrodes are identical. A mathematical expression of figure of merit for devices that do not have current densities at both ends equal is not known.

The current state of the art is characterized by materials having figures of merit up to (3.0-3.5)×10⁻³K⁻¹. It should be emphasized that, in actual device applications, there are other heat losses in the system and the efficiency is never fully realized.

The improvement of efficiency of thermoelectric devices is a major objective of the electric energy industry, conservationists and environmentalists. With improved efficiency of thermoelectric devices, even a small one, let us say 10 to 15%, significant portions of energy lost as waste heat by power generating stations and heavy industry could be recovered as useful electricity. Recovering waste energy would increase overall electrical energy efficiency by reducing fuel consumption.

### SUMMARY OF THE INVENTION

In view of the forgoing problems and mainly low conversion efficiency, the present invention has been devised, and it is an object of the present invention to provide a structure and method for improving energy conversion device.

In order to enhance the converting efficiency of the thermoelectric device, there are provided, according to one aspect of the invention, uneven current densities at both ends of connecting electrodes that includes in the example a circular structure.

Another object of the present invention is to design a thermoelectric device improved in mechanical ruggedness and simplicity helpful in assembly automation.

Still another object of the present invention is to provide a process according to which thermoelectric devices of the kind as described above can be manufactured with high yield and low manufacturing cost.

In the following text frequent references will be made to the first type thermoelectric material and to the second type thermoelectric material. The term “first type thermoelectric material” will be used to describe a conductive media in which the positive voltage develops at the contact of the thermoelectric device that is heated. The term “second type thermoelectric material” will be used to describe a conductive media in which the negative voltage develops at the contact of the thermoelectric device that is heated. An example of the first type thermoelectric material is an n-type semiconductor and conversely, the second type thermoelectric material is a p-type thermoelectric material.

In the first aspect of the present invention, a thermoelectric device cell, comprises: a first circular disc made of the first type thermoelectric material, electrically connected to the pair of metallic electrodes, first inner contacting electrode having a small radius and the second outer contacting electrode having a large radius and a second circular disc made of a second type thermoelectric material, electrically connected to the second pair of contacting electrodes, one inner contacting electrode having a small radius and the outer contacting electrode having a large radius. One contacting electrode of the first circular disc is the application end, the second contacting electrode is connected to the second disc of alternate diameter of the second thermoelectric disc, and the complimentary second electrode of the second disc is connected to the appliance.

In the second aspect of the present invention, a thermoelectric battery, comprises: a plurality of thermoelectric device cells arranged and connected in series in order to increase the operating voltage for simplified utilization.

The above and other objects, features, and features will be more clearly understood and appreciated upon considering the detailed embodiments thereof taken in conjunction with the accompanying drawings.

### BRIEF DESCRIPTION OF THE DRAWINGS

Other objects, advantages, features and characteristics of the present invention, as well as methods, operation and functions of related elements of structure, and the combination of parts and economics of manufacture, will become apparent upon consideration of the following description and claims with references to the accompanying drawings, all of which form a part of this specification, wherein like reference numerals designate corresponding parts in the various figures.

FIG. 1 depicts an assembly of the thermoelectricity generator. The heat, applied to one side of the device assembly and with the second side of the assembly maintained at constant temperature, is converted into electrical energy.

FIG. 2a shows a conventional rectangular Seebeck/Peltier cell connected to a current source in the Peltier cooling mode. The electric current I₁, connected to the battery 105 via switch 105, generates cooling on the negative side 102 of the first type thermoelectric material 101 and generates heat on the positively biased end 103 of the thermoelectric cell. The voltmeter/power indicator 106 not connected.

FIG. 2b shows the new circular Seebeck/Peltier cell. connected to a current source in the Peltier cooling mode. The electric current I₂, connected to the battery 105 via switch 105, generates cooling of the circular perimeter 202 of the first type thermoelectric material 101 and it provides heating near the circular electrode 203 of the thermoelectric cell. The voltmeter/power indicator 106 is not connected.

FIG. 3a shows a conventional rectangular Seebeck/Peltier cell in the Seebeck mode with one side hot 103 and one side cold 102. The device is electrically connected via switch 104 to a voltmeter/power indicator 106 that is indicating the amount of electrical potential generated in the Seebeck/Peltier cell. The thermoelectric material 101 is of the first type and the hot electrode 103 is exhibiting a positive voltage potential with respect to the cold, negatively biased electrode 102.

FIG. 3b shows the new circular Seebeck/Peltier cell connected in the Seebeck mode. The hot electrode 203 generates electric current of positive polarity and the cold electrode 202 generates electric current of negative polarity. Power/voltage indicator 106 indicates the amount of power/voltage generated by the cell. The thermoelectric material 101 is of the first type.

FIG. 4a shows a conventional rectangular Seebeck/Peltier cell of the second thermoelectric type 201 in the Peltier mode connected to the battery 105 via switch 104. The electric current I₅ generates cooling on the positively biased electrode 103 and generates heating on the negatively biased end 102. The power/voltmeter is not connected.

FIG. 4b shows the new circular Seebeck/Peltier cell connected in the Peltier mode. The cell material is of the second type 201. The battery 105 is connected to the cell via switch 104. The electric current I₆ generates cooling of the positively biased center electrode 203 and the negatively biased outer electrode 202 is heated.

FIG. 5a shows a conventional rectangular Seebeck/Peltier cell in the Seebeck mode with one side hot 102 and one side cold 103. The device is electrically connected to a power/voltage indicator 106 that indicates the amount of power or electrical potential generated by the cell. The thermoelectric material 201 is of the second type and the hot electrode is generating a negative potential and the cold electrode is charged positively.

FIG. 5b shows the new circular Seebeck/Peltier cell connected in the Seebeck mode. The cold electrode 203 generates electric current of positive polarity and hot electrode 202 generates electric current of negative polarity. The power/voltage indicator 106 reveals information on the amount of power/voltage produced by the cell. The thermoelectric material 201 is of the second type.

FIG. 6 illustrates the assembly of the generator. Starting from the left, the negative output electrode 400 is connected to the outside perimeter of the first thermoelectric cell of the first thermoelectric material. The inner electrode 203 of the first cell is connected with conductor 300 to the inner electrode 203 of the second cell of the second thermoelectric material. The outer electrode 202 of the second thermoelectric cell is connected with conductor 301 to the outside metal electrode 202 of the third cell. The individual thermoelectric cells at the opposite end are connected in the same manner. The outside electrode of the last cell made of the second type thermoelectric material is connected to the outside electrode with connection 400 and the output is of the positive polarity.

FIG. 7 illustrates a single thermoelectric cell. The cell is made of the first type thermoelectric material 101 and the metal rings 202 and 203. The rings provide electrical connections to the thermoelectric material. The radius r₂>r₁≧0.

FIG. 8 illustrates the complimentary thermoelectric cell to the cell shown in FIG. 7. This cell is made of the second type thermoelectric material 201 and the two metal rings 202 and 203. The rings provide electrical connections to the thermoelectric material. The radius r₂>r₁≧0.

FIG. 9 shows the thermoelectric material 101 of the first type without the metal connections.

FIG. 10 shows the thermoelectric material 201 of the second type without the metal connections.

FIG. 11 illustrates the outer metal electrode common to both types of thermoelectric materials.

FIG. 12 illustrates the inner metal electrode common to both types of thermoelectric materials.

### DETAILED DESCRIPTION OF THE PREFERRED EMBODIMENT

In the following detailed description of the preferred embodiments, reference is made to the accompanying drawings which form a part hereof, and in which is shown by way of illustration specific preferred embodiments in which the invention may be practiced. These embodiments are described in sufficient detail to enable those skilled in the art to practice the invention, and it is to be understood that other embodiments may be utilized and that logical, mechanical and electrical changes may be made without departing from the spirit or scope of the invention. To avoid detail not necessary to enable those skilled in the art to practice the invention, the description may omit certain information known to those skilled in the art. The following detailed descriptions, therefore, not to be taken in a limiting sense, and the scope of the present invention is defined only by the appended claims.

The conceptual ground work for the present invention involves fabricating a heat to electricity converting device having a round or nonlinear shape for improved efficiency. In this manner, thermal to electricity conversion and heat management is utilized efficiently.

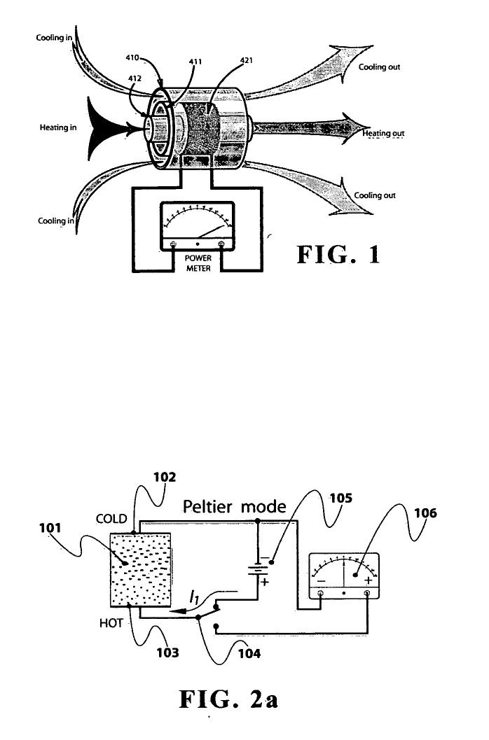

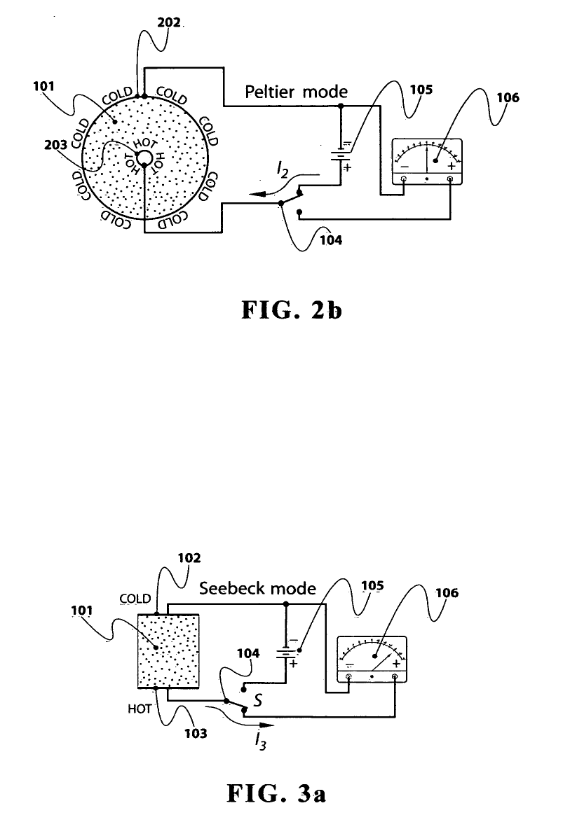

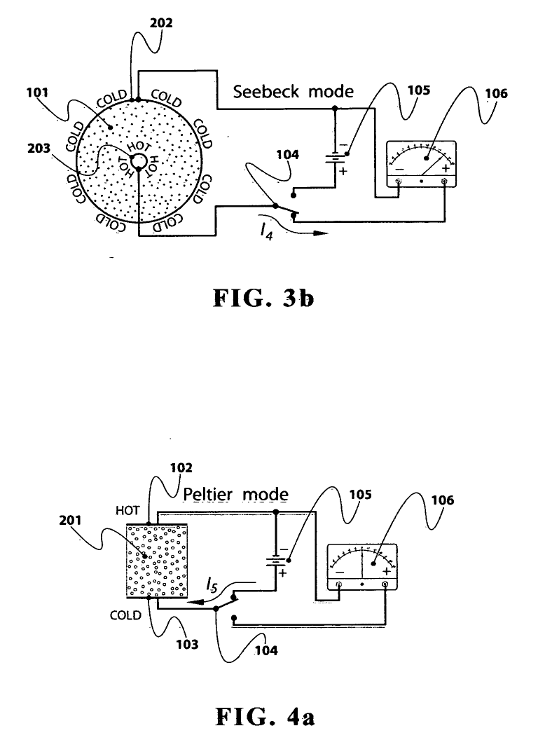

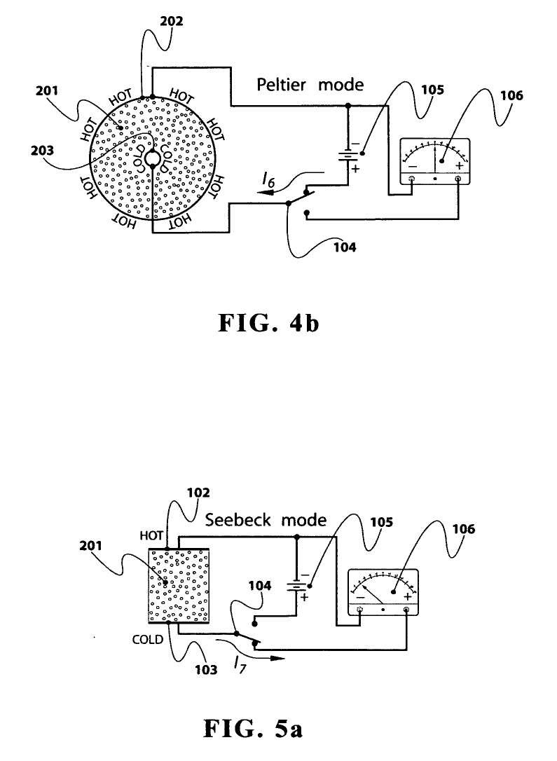

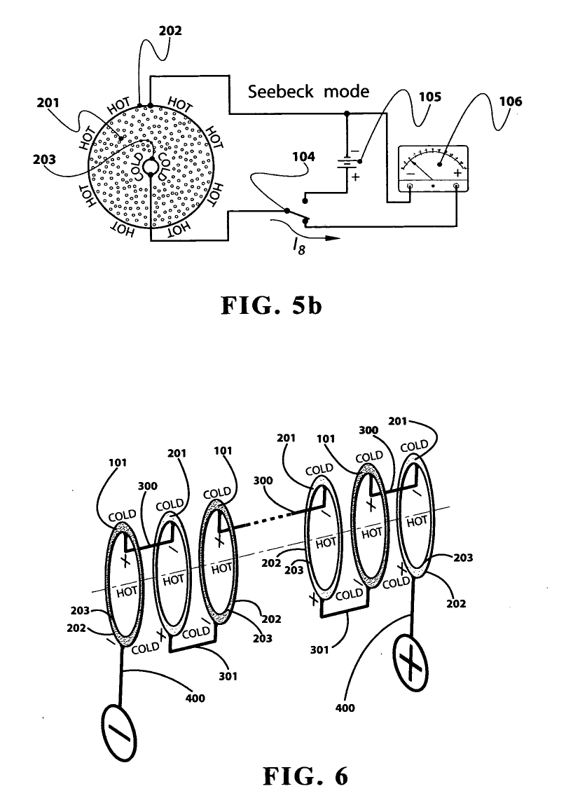

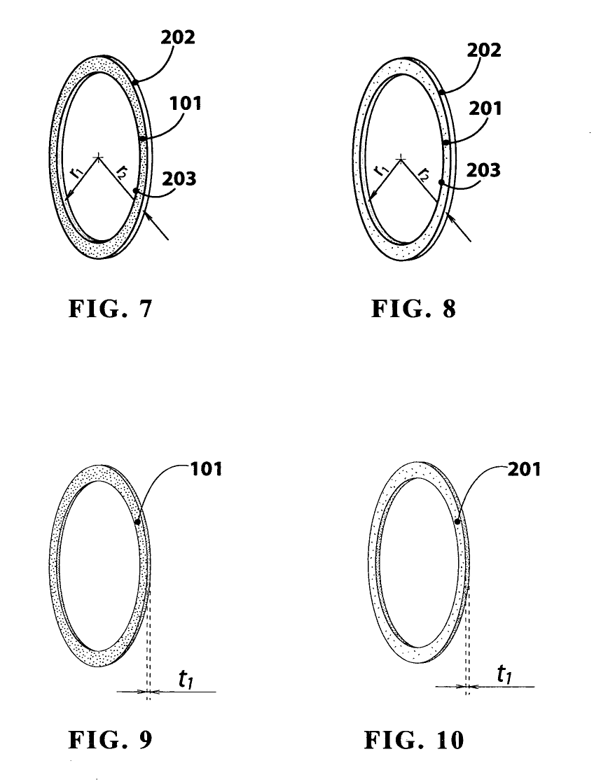

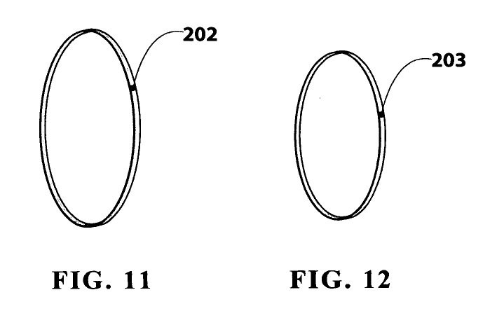

Referring to FIG. 1, the basic element of an exemplary thermoelectricity generator is an individual thermoelectricity cell shown at 7 and 8. The individual thermoelectricity cell 7 comprises a couple of metal electrodes 202 and 203, a metal to thermoelectric material 101 and 201 junctions formed between the metal rings 202 and 203 and the thermoelectric material of the first and second type, 101 and 102. Each cell comprises two metal electrodes of opposite polarities. The electrode 203 connected to the thermoelectric material of the first type 101 in 7 has an opposite polarity than the electrode 203 connected to the thermoelectric material of the second type 201 in 8 and the electrode 202 connected to the thermoelectric material of the first type 101 in 7 has an opposite polarity than the electrode 203 connected to the thermoelectric material of the second type in 8. In the exemplary embodiment illustrated in 6, the electrode 202 of the first thermoelectric cell 101 is connected to outside terminal 400 as the negative output and the second electrode 203 is connected via conductor 300 to the electrode of the opposite polarity 203 of the opposite polarity of the second type of thermoelectric material 201. The outputs of each cell are electrically connected and the total voltage output between output electrodes is the sum of the voltages of individual cells. The cells are sandwiched and sealed thereby providing the thermoelectricity generator 1. Additional mechanical tubing 410, 411 and 412 may be provided to contain and guide the heating and cooling substances. The assembly 421 is protected from adverse conditions.

Many alternate embodiments consistent with the present invention may be derived from the above described assembly 1. The number of individual cells may be varied according to specific needs and the output voltage may be selected.

In the described thermoelectric generator, the heating medium may be an automobile exhaust, industrial exhaust, nuclear originated heat or organic heat to name a few examples. The temperature of the cold side end of the thermoelectric generator may be controlled by the air flow or by circulated water for example.

1. A non linear, circular, spherical, planar and two or three dimensional thermoelectricity generator comprising thermoelectric conductors of the first, second or both types, inner and outer rings providing contacts to the thermoelectric material.

2. The thermoelectric module of claim 1, which could function as an efficient thermoelectricity generator or by reversing the function, applied electricity to the module could act as an effective cooling device.

3. The thermoelectric module of claim 1, wherein the reduction of difference between radii r₁ and r₂ would produce conduction by tunneling of charges from ring to ring.

4. The thermoelectric module of claim 1, wherein the conduction between electrodes is caused by ionized matter.

5. In a method of fabricating the thermoelectric cell, wherein molten thermoelectric material of the first or the second type is placed between concentric pipes that are inexpensively sliced into wafers and each wafer is used as a thermoelectric cell.

6. In a method of fabricating the thermoelectric cell, wherein the inner electrode is eccentrically located.

7. The method of claim 6, wherein the close distance between electrodes promotes carrier tunneling in addition to electrical conduction.
